(19) United States
(12) Patent Application Publication
(10) Pub. No.: US 2021/0168320 A1
(43) Pub. Date: Jun. 3, 2021

(54) MULTILINEAR IMAGE SENSOR WITH CHARGE TRANSFER WITH INTEGRATION TIME ADJUSTMENT

(71) Applicant: Teledyne e2v Semiconductors SAS, Saint Egreve (FR)

(72) Inventors: Frédéric BARBIER, Fontanil-cornillon (FR); Frédéric MAYER, Voiron (FR); Pierre FEREYRE, Voreppe (FR)

(21) Appl. No.: 16/071,229

(22) PCT Filed: Jan. 16, 2017
(86) PCT No.: PCT/EP2017/050815

§ 371 Date: Jul. 19, 2018

(30) Foreign Application Priority Data
Jan. 22, 2016 (FR) 1650511

(51) Int. Cl. H04N 5/372; H01L 27/148; H04N 5/353

(52) U.S. Cl. CPC H04N 5/37206; H04N 5/353; H01L 27/14818; H01L 27/14856

(57) ABSTRACT

The invention relates to charge-coupled TDI image sensors for the observation of one and the same image strip by multiple rows of pixels in succession with summation of the electric charge generated by an image point, for a row duration (T_{L} ), in the pixels of the same rank of the various rows. According to the invention, the pixels are subdivided, in the direction of movement, into at least two adjacent portions (SUBa_{i,j}, SUBb_{i,j}), each portion comprising at least one charge storage area that is independent of the storage areas of the other portion while allowing a transfer of charge from the first portion to the second, one of the portions (SUBa_{i,j}) being masked against light and the other portion (SUBb_{i,j}) not being masked. The unmasked portion comprises a charge removal structure which is activated at a variable moment in time defining a start of actual integration that is independent of the start of a period of observing the image strip. It is thus possible to define a time of exposure to light T_{INT} that does not depend on the relative speed of movement of the sensor and of the image, unlike the typical charge-coupled TDI sensors in which the duration of exposure is equal to the row period T_{L} (linked to the speed of movement).

### TECHNICAL FIELD

The invention relates to time delay integration linear image sensors (or TDI image sensors) in which an image of a strip of points of an observed scene is reconstructed by adding signals collected by multiple rows of photosensitive pixels observing one and the same strip of the scene in succession as the scene moves past in front of the sensor.

### PRIOR ART

These sensors are, for example, used in scanners. They comprise a linear array of multiple parallel rows of photosensitive pixels; the sequencing of the control circuits for controlling the various rows (control of exposure time then readout of the photogenerated charge) is synchronized with the relative movement of the scene and of the sensor, so that all of the rows of pixels of the sensor see one and the same strip of the observed scene in succession. The signals generated by each row are subsequently added, point by point, for each point of the observed strip.

For a constant exposure time, the sensitivity of the sensor is improved in proportion to the number N of rows, or else, for a constant sensitivity, the exposure time may be divided by N. This number N may be, for example, 16 or 32 for industrial control applications. The signal-to-noise ratio is improved proportionally to the square root of the number N of rows of the sensor.

There are TDI image sensors in which the pixels are active pixels comprising a photodiode and multiple transistors, and in which signals arising from the pixels are added digitally, i.e. the analogue signal arising from each pixel is digitized, and the digital values arising from pixels that have seen the same image point are subsequently added.

There are also charge-coupled TDI image sensors in which the pixels are passive (comprising only charge generation and charge storage areas) in which the point-by-point addition of the signals is an addition of electric charge collected by the various pixels that have seen the same image point. This addition is achieved simply by emptying the charge generated and accumulated in one row of pixels into the following row of pixels, in sync with the relative movement of the scene and of the sensor. The last row of pixels, having accumulated N times the charge generated by the observed image strip, may be read out and may then be digitized.

Such sensors are mainly produced using CCD technology and will increasingly be produced using CMOS technology. Each pixel comprises gates for storing the electric charge generated by light. The charges are generated in the semiconductor covered by the gates, or in photodiodes which are sometimes intercalated between two successive gates. The sensor comprises control means for controlling the potentials applied to the gates in order to move the electric charge from one gate to the other, simultaneously for all of the pixels, in N successive steps if there are N rows in the TDI sensor.

An exemplary charge-coupled TDI sensor is provided in the patent EP 2 482 317. In this example, the pixel comprises a succession of gates and photodiodes, for example four gates and four photodiodes, alternately, with uniform doping of the semiconductor below the gates; the control of the gates comprises four phases; the pixel may also comprise three gates and three photodiodes in alternation and three-phase control. Another example is provided in the patent U.S. Pat. No. 6,465,820. In this other example, a pixel comprises only one gate and one photodiode and the control of the gates comprises only two phases due to the particular dopings in the semiconductor, both in the photodiode and below the gate.

In these various examples, the semiconductor is photosensitive, both below the gates and in the photodiodes, i.e. the light illuminating the pixel generates electric charge representative of this illumination both below the gates and below the photodiodes. Depending on the phase in question during the charge transfer, the photogenerated charge is stored either below the gates or below the photodiodes, or else below both at the same time. The succession of phases gradually transfers the charge from one storage region to another located downstream of the first.

The present invention relates to charge-coupled TDI sensors rather than digital summation sensors.

It has been observed that these charge-coupled sensors may have a drawback when the relative speed of movement of the sensor and of the image fluctuates. Specifically, the cyclic operating period of the pixels is adjusted precisely according to the speed of movement in order to provide true TDI operation. When the movement is imposed by a mechanism external to the sensor, for example for the observation of objects placed on a conveyor belt, the operation of the phases of the sensor is generally slaved to the speed of movement of the conveyor belt and the period T_{L} of transfer of charge from one row of pixels to the next, which may be referred to as the “row time”, is slaved to the speed of movement. Fluctuations in the speed of movement may occur and are compensated for: TDI operation is not disrupted since the successive rows of pixels will always view the same physical strip height on the scene by virtue of the slaving that is effected. The light integration time, which is equal to the row time T_{L}, is equal to DN if the relative speed of movement of the image projected onto the pixels is V and if the spacing of the rows of pixels is D.

If the speed of movement V varies, the exposure time will vary accordingly, in inverse proportion to the speed. The duration of exposure of the rows of pixels therefore varies according to fluctuations in the movement, thereby leading to interference in the fidelity of the image produced by the sensor.

There are circumstances under which the avoidance of fluctuations in exposure time is desired, for example in a device for observing objects moving past on a conveyor belt. Upon starting the conveyor belt, and even during operation, the speed may fluctuate very substantially and cause interference in the collected image.

It has therefore been observed that it might be desirable, in certain cases, to decorrelate the light integration time T_{INT} and the row time T_{L}. In the pixels of charge-coupled TDI sensors of the prior art, it is not possible to make the charge integration duration T_{INT} shorter than the row duration T_{L}.

### SUMMARY

The invention therefore proposes a charge-coupled TDI image sensor, the pixels of which are constructed so as to allow a variable light integration duration T_{INT} to be set up that is shorter than or equal to the duration T_{L} of periodicity of the transfer of charge from one row of pixels to the next.

To this end, the pixel is divided into at least two portions in the direction of the transfer of charge from row to row, each portion being capable of storing electric charge, one of the portions being masked from light and the other portion being unmasked. The unmasked portion is equipped with a charge removal structure, which may be controlled in order to remove and eliminate charge stored in this portion. The removal of charge stored in the unmasked portion does not lead to the removal of charge from the masked portion; the latter retains the charge that has been integrated in a preceding period; the actual integration of charge in the unmasked portion begins only after the end of a charge removal command since any charge potentially collected in this unmasked portion is eliminated during the execution of this command. Thus, the charge integration time may be limited to a duration that is shorter than the row period without this leading to the elimination of charge arising from the pixels of the preceding rows, this charge remaining provisionally stored in the unmasked portion and unaffected by the removal of charge from the unmasked portion.

The invention therefore proposes a charge-coupled image sensor operating with time delay and charge integration, the sensor comprising N adjacent rows of P pixels for observation of one and the same image strip by multiple rows of pixels in succession with summation of the electric charge generated by an image point, for a periodic row duration, in the pixels of the same rank of the various rows, the pixels each comprising a succession, in the direction of movement, of charge storage areas, at least some of which are photosensitive, the sensor comprising control means for applying potentials to these areas allowing the storage followed by the directional transfer of charge from one pixel to the next, characterized in that a pixel is subdivided, in the direction of movement, into at least two adjacent portions, each portion comprising at least one charge storage area that is independent of the storage areas of the other portion while allowing a transfer of charge from the first portion to the second, one of the portions being masked against light and the other portion not being masked against light, the latter comprising at least one photosensitive storage area and charge removal structure allowing the charge stored in this other part to be removed, the charge removal structure being activated for a fraction of a row duration, before an adjustable instant in time of the start of actual integration preceding a step of transferring charge from the masked area to the unmasked area.

The invention is applicable to all charge-coupled TDI sensor structures, regardless of the number of storage areas in the pixel (at least two areas to allow transfer) and regardless of the number of operating phases allowing the transfer of charge from one pixel to another in a row period T_{L}. It is also applicable both when the storage areas are insulated conductive gates surmounting a portion of semiconductor substrate and when the storage areas are photodiodes, especially “pinned” photodiodes, i.e. photodiodes having a fixed surface potential. In one advantageous embodiment, the pixel of a sensor according to the invention may comprise three adjacent gates coming one after the other in the direction of movement, the first gate being masked from light and forming the first portion of the pixel and the other two being lit and forming the second portion of the pixel, the charge removal structure being adjacent to said other two gates. In another advantageous embodiment, the first portion of the pixel will comprise in succession, in the direction of movement, two gates and a photodiode, and the second portion will also comprise two gates and a photodiode, and the charge removal structure is adjacent to the photodiode of the second portion.

The invention also pertains to an operating method for a charge-coupled TDI image sensor operating with time delay and charge integration, the pixels of which are divided into a masked portion and an unmasked portion. In the method according to the invention, the sensor comprises N adjacent rows of P pixels for observation of one and the same image strip by multiple rows of pixels in succession with summation of the electric charge generated by an image point, for a row duration T_{L}, in the pixels of the same rank of the various rows, the pixels each comprising a succession, in the direction of movement, of charge storage areas, at least some of which are photosensitive, the sensor comprising control means for applying potentials to these areas allowing the storage followed by the directional transfer of charge from an upstream pixel to a downstream pixel, characterized in that a portion of the storage areas of each pixel is masked from light and another portion is not masked and is photosensitive, and in that the movement and integration of charge comprise, cyclically with a periodicity equal to one row duration T_{L}:
the transfer of charge arising from the upstream pixel to a storage area of the masked portion of the downstream pixel;
a command to empty, via a removal drain, the charge contained in the unmasked portion of the downstream pixel, followed by the cessation of this command, defining an instant in time of the start of actual charge integration in the downstream pixel;
simultaneously or separately, the integration of photogenerated charge in the unmasked portion of the downstream pixel and the transfer of the charge stored in the masked portion of the downstream pixel to the unmasked portion of the downstream pixel.

### BRIEF DESCRIPTION OF THE DRAWINGS

Other features and advantages of the invention will become apparent upon reading the detailed description which follows, provided with reference to the appended drawings in which:

FIG. 1 provides an exemplary TDI sensor pixel structure according to the invention, with three storage gates per pixel, one of which is masked from light;

FIG. 2 shows an operating timing diagram for the pixel of FIG. 1;

FIG. 3 shows a sensor pixel structure according to the invention, with two subdivisions each comprising two storage gates and one photodiode;

FIG. 4 shows an operating timing diagram for the pixel of FIG. 3.

### DETAILED DESCRIPTION

The invention will first be described for a particularly simple case in which all of the charge storage areas are formed using insulated conductive gates, and the charge is generated in the subjacent semiconductor substrate by the light that passes through the insulated gates (generally made of polysilicon). However, the invention is also applicable, as will be seen, to the case in which some of the storage areas are photodiodes.

In general, the photosensitive pixels of an image sensor are formed in a semiconductor substrate, the upper portion of which is a lightly doped epitaxial semiconductor layer. The substrate is, for example, of heavily doped p-type and the epitaxial layer is also of p-type, but less heavily doped, and the potentials applied to the gates in order to form potential wells that are capable of holding charge are positive potentials while the potentials applied to the gates in order to form potential barriers are generally zero or negative potentials, the zero reference potential being the potential of the epitaxial layer.

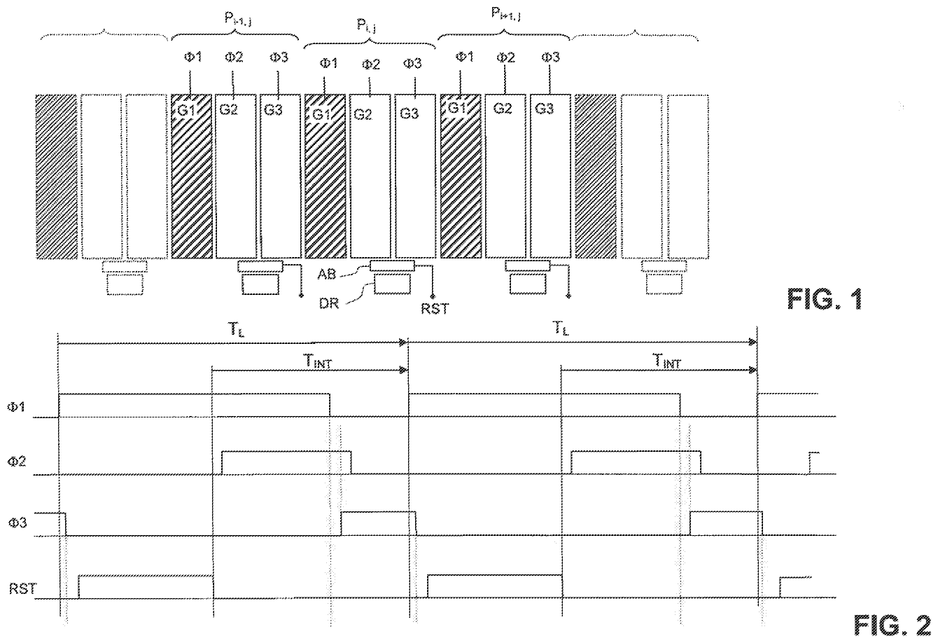

FIG. 1 shows the case of an image sensor the pixels of which are each formed by three adjacent gates coming one after the other in the direction of charge transfer, i.e. in the relative direction of movement of the sensor with respect to the image to be observed projected onto the sensor, which is the direction of the columns of pixels, perpendicular to the direction of the rows of pixels.

Three successive pixels belonging to one and the same column of rank j are schematically shown in plan view. They are denoted by P_{i-1, j}; P_{i, j}; and P_{i+1, j} in order to indicate that they belong to three successive rows of rank i−1, i, and i+1, respectively. The pixels of the other columns are not shown; there is no transfer of charge between the pixels of different columns.

Each pixel comprises three adjacent gates G1, G2, G3 coming one after the other in the direction of charge transfer and corresponding to three possible storage areas, in the semiconductor below the respective gate, for the charge that flows from one row of pixels to another. The gates are controlled by respective signals Φ1 for gate G1, Φ2 for gate G2 and Φ3 for gate G3, which signals are the same for all of the pixels. The last gate G3 of an upstream pixel is adjacent to the first gate G1 of a downstream pixel in order to allow charge to be transferred from one pixel to the next. The control signals Φ1, Φ2, Φ3 applied to a gate G1, G2, G3, depending on the other signals applied to the gates which are adjacent thereto, either allow charge to be stored below this gate or allow charge to be transferred to another gate (of the same pixel or of an adjacent pixel).

According to the invention, the pixels are subdivided into two portions. Electric charge may be stored independently in each of the two portions. One of the portions is masked from light, for example by an opaque metallization layer; the other is exposed to light. In the example shown, the first portion essentially corresponds to the first storage area (gate G1); the gates G1 are hatched to show here that the gate is either made of an opaque material or, preferably, masked from light by an opaque layer; in practice the gate is made of polysilicon, and it is covered by an opaque metallization layer of aluminium or of a conductive material. The optical mask is either passive and connected to ground, or active and used to convey control signals. Furthermore, according to the invention, provision is made for a structure for removing the charge contained in the second and third storage areas, i.e. below the gates G2 and G3 of the unmasked portion. This structure may be formed conventionally by:
a reset gate AB adjacent on one side to the second and third storage areas;
a removal drain DR (typically an n+-doped diffusion region brought to a positive supply potential, if the photogenerated charge is composed of electrons) adjacent to the reset gate on the other side.

The sensor comprises means for activating the reset gate AB in order to bring it to a high potential allowing a removal of charge, from the unmasked portion to the drain in which this charge is eliminated, to be periodically triggered.

The removal of charge is here understood to be a removal out of the storage areas; the removed charge is eliminated from these areas, it is lost and not stored, and it no longer participates in the charge accumulation and transfer process.

The architecture of the charge-coupled TDI image sensor therefore comprises pixels with multiple storage areas per pixel, which are defined by three gates in the case of FIG. 1, and they have, in each pixel, a masked portion, an unmasked portion and a structure for removing charge from the entire unmasked portion, with the corresponding control means. The masked portion decreases the efficiency of photoelectric conversion since the light-collecting area of the pixel is then smaller than it could otherwise be, but the advantage is that the integration duration T_{INT} for the observation of a strip for a row period T_{L} is then freely adjustable by choosing the instant in time and duration of activation of the reset gate.

It will furthermore be noted that the reset gate and the removal drain may be used as an anti-blooming system when the gate is not activated, in the sense that the low potential applied to the gate outside of the activation periods may be set to a non-zero, for example slightly positive, value, which allows the charge that threatens to saturate the storage areas and disrupt the neighbouring pixels to be removed via the drain before this saturation occurs. For simplicity, the low potential applied to the reset gate outside of the activation instants in time will hereinafter be considered to be a zero potential.

The operation of this sensor is based, as in all charge-coupled structures, on the creation of potential wells for storing charge and of potential barriers around the wells to confine the stored charge. It is assumed, as usual, that the generated charge is composed of electrons, the potential wells are therefore created by applying positive potentials to a gate, and the potential barriers are created by applying zero potentials (or in any case potentials that are less positive than the potentials that create the deepest wells).

A situation is first considered in which only the (unmasked) gates G3 receive a positive potential and create a charge-retaining potential well below these gates; this charge is at the moment an accumulation of charge arising from pixels located upstream in the direction of charge transfer and having previously viewed the same image point in the preceding observation periods; the regions below the gates G2 and G1 (at a low potential) form potential barriers confining the charge below the gates G3. The gates of the pixels are then controlled in order to have the following succession of steps:

a) a positive potential is applied to the gates G1 in order to create a potential well (empty of charge), then the potential of the gates G3 is lowered: the charge present below the gate G3 of each pixel being transferred at that moment to below the gate G1 of the following pixel (downstream pixel);

b) a reset signal RST, which is a positive potential for activating the removal structure, is applied to the gates AB, and this potential is held in order to prevent any accumulation of charge below the gates G2 and G3 for a duration chosen as a function of the desired duration T_{INT} of integration of charge in the pixels for a row period T_{L} corresponding to the speed of movement (T_{L}=D/V); the charge stored or created below the gates G2 and G3 is removed and lost; that which is stored below the gates G1 is retained;

c) the reset signal RST is stopped, which defines the start of the integration duration TINT;

d) the integration of photogenerated charge takes place below the transparent gates G2 and G3;

e) the potential of the gates G2 is raised again so that this charge is stored below the gates G2;

f) the potential of the gates G1 is subsequently lowered, so that the charge stored below the gates G1 moves to below the adjacent gates G2 and remains there; the potential well below the gates G2 then comprises the charge previously stored below the gates G1 (step a) and the charge currently generated by the illumination of the pixel (step e onwards);

g) the potential of the gates G3 is raised; the charge is distributed between the gates G2 and G3; the accumulation of charge resulting from the current illumination of the unmasked gates G2 and G3 continues below these gates;

h) the potential of the gates G2 is lowered again, and the charge is grouped below the gates G3 and comprises, besides the accumulated charge, the charge photogenerated below the (unmasked) gates G2 and G3 in the current observation period;

i) the end of the current observation period, hence the end of the integration duration T_{INT}, occurs when the potential of the gates G1 is raised again in order to move to step a) of a new observation period T_{L}. The charge that will then be transferred to the gate G1 of each pixel includes not only the prior accumulations from the pixels located upstream but also the charge integrated in the pixel in question over the duration T_{INT} that has just elapsed.

If the end of the charge integration period is defined as the instant in time at which the potential of the gates G1 is raised again, then it may be seen that a start of integration has been defined at a moment in time corresponding to step c), which may be defined freely, rather than step a) as would have been the case in the prior art. This is possible by virtue of the masking of the area G1 (preventing it from continuing to directly accumulate charge) and by virtue of the charge below the gates G2 and G3 having been allowed to be emptied without emptying the charge below the gates G1.

FIG. 2 shows the corresponding operating timing diagram. Its particularity with respect to the operation of a more conventional TDI structure, the pixels of which would also comprise three gates, is the presence of an RST command for controlling the gate AB, activated before the start of an integration duration and therefore preventing the integration of charge, while a conventional structure comprises integration for the entire strip observation duration T_{L} (row period).

The signals of this timing diagram are the following:
signal Φ1 for controlling the gates G1
signal Φ2 for controlling the gates G2
signal Φ3 for controlling the gates G3
signal RST for controlling the removal gate AB

These signals are activated periodically (period T_{L}) in the following order, corresponding to steps a) to f) described above:

Step a)

The rising edge of the signal Φ1 defines the start of a row period and creates a potential well below the gates G1.

The falling edge of the signal Φ3, coming shortly after the rising edge of the signal Φ1, then allows the charge to be transferred from the gate G3 to the gate G1 of the next pixel. This charge is the charge resulting from the illumination of the pixels which have viewed the same image strip over the preceding periods.

Step b)

The rising edge of the signal RST, coming shortly after the falling edge of the signal Φ3, allows the charge generated by light below the illuminated gates G2 and G3 to subsequently be eliminated via a drain.

Step c)

The falling edge of the signal RST makes it possible to allow the new charge generated below the gates G2 and G3 of the pixel to be retained. It is this falling edge that defines the start of the integration of photogenerated charge (Step d).

Step e)

The rising edge of the signal Φ2, coming shortly after the falling edge of the signal RST, creates a potential well allowing the charge photogenerated below the gates G2 and G3 to subsequently be accumulated below the gate G2.

Step f)

The falling edge of the signal Φ1, coming after the rising edge of the signal Φ2, allows the charge stored below the gate G1 and resulting from accumulations of the preceding periods to be transferred to the potential well below the gates G2.

Step g)

The rising edge of the signal Φ3, coming after the rising edge of the signal Φ2, allows the charge below the gate G2 to be distributed below the gates G2 and G3.

Step h)

The falling edge of the signal Φ2 allows all of the charge to move to below the gate G3.

Step i)

The rising edge of the signal Φ1, which defines the start of a new row period, creates a potential well to which the charge present below the gate G3, resulting, on the one hand, from the prior accumulations and, on the other hand, from the generation of charge by light in the current pixel over the period that has just elapsed, will subsequently be transferred.

It will be noted that the transfer of charge from the masked portion to the unmasked portion of a pixel may be carried out at any moment in time after the end of the signal RST for activating the charge removal structure but not before the end thereof.

It will be understood that this operation can be easily transposed if the nature of the storage areas is changed, i.e. in particular if some thereof are defined not by gates as in the preceding example but by photodiodes, in particular photodiodes having a fixed surface potential (“pinned photodiodes”). Likewise, this operation remains easily transposable if the pixels comprise a number of storage regions other than three, provided that the principle of the present invention is retained, namely the presence in the pixel of a subdivision that is masked from light and the presence of a command for removing the charge generated in the other subdivision, which remains illuminated. Lastly, the principle of the invention is applicable both to the case of storage regions below the gates which have a constant doping profile and to the case of storage regions having doping profiles which differ from the upstream side to the downstream side, as is often done to decrease the number of gate control phases, by introducing a directionality of transfer due to these particular doping profiles.

An example of operation of the invention, with a pixel comprising four gates and two photodiodes, split into two subdivisions, one of which is masked and the other of which is illuminated, will be given below.

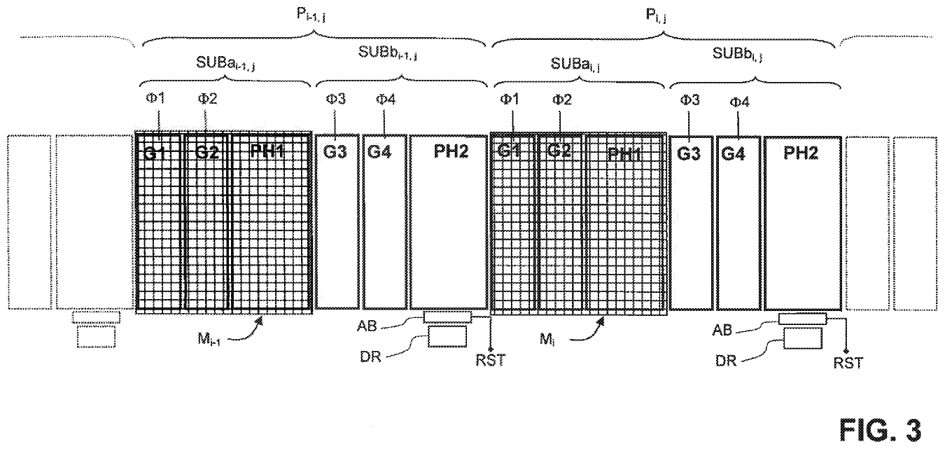

FIG. 3 shows in a view from above a column of pixels with two consecutive pixels and P_{i-1,j} and P_{i,j} of rank i−1 and i, respectively. The pixels each comprise two subdivisions denoted by the indices a and b, respectively, namely SUBa_{i-1,j} and SUBb_{i-1,j} on the one hand, and SUBa_{i,j} and SUBb_{i,j} on the other hand. The first subdivision of each pixel is masked by a mask, Mᵢ₋₁ for the pixel P_{i-1,j} and Mᵢ for the pixel P_{i,j}. The masks are represented by gridded areas allowing the gates and photodiodes which make up this subdivision of the pixel to be seen.

The first subdivision comprises two gates G1 and G2 and a photodiode PH1 in succession. The gates and the photodiode define charge storage regions. The second subdivision comprises two gates G3 and G4 and a photodiode PH2 in succession. A charge transfer is possible between two successive gates or between a gate and a following photodiode, or between a photodiode and the following gate.

The gates G1, G2, G3, G4 are controlled by logic signals Φ1, Φ2, Φ3, Φ4, respectively. The photodiodes are not controlled, they are preferably “pinned” photodiodes, the surface potential of which is zero by design and which set up an intrinsic potential well that is capable of collecting charge. Of course, a structure with photodiodes with a controlled surface potential may also be envisaged.

Provision is made for a reset gate and a charge removal drain associated with the unmasked subdivision in the pixel of FIG. 1; this gate and this drain are associated with the photodiode PH2; the reset gate, controlled by an activation signal RST, is therefore adjacent to the photodiode. It is not necessary to make provision for the reset gate to be directly adjacent to the gates G3 and G4 of the unmasked subdivision, as the moment in time of activation of this gate will occur at a moment in time at which all of the charge which might have been stored below the gates G3 and G4 would already have been transferred to the photodiode PH2.

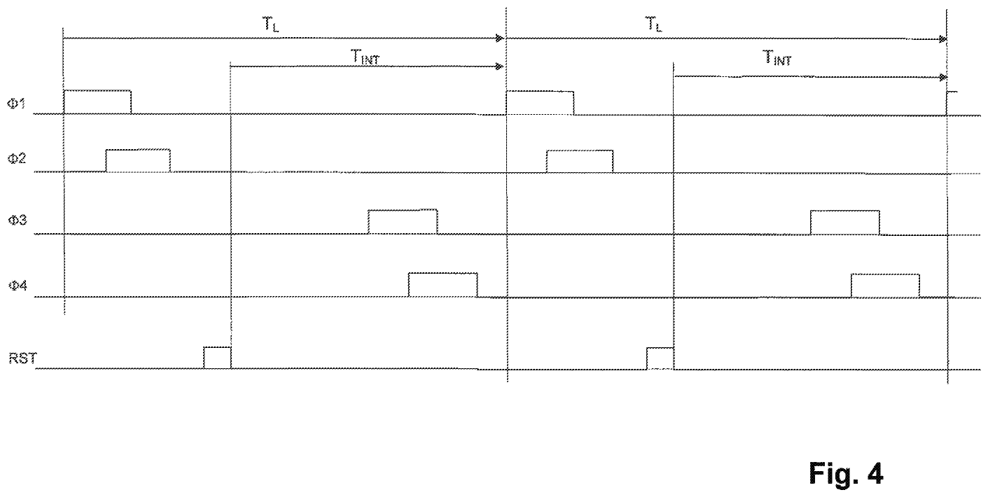

The operation is as follows, described with reference to the timing diagram of FIG. 4 which shows the various signals Φ1, Φ2, Φ3, Φ4 and RST, which, here again, have a periodicity of one row time T_{L}=DN but an integration duration T_{INT} that may be shorter than T_{L} and which is defined by the end instant in time of the signal RST for activating the removal.

The start of the row period may be defined as being the rising edge of the signal Φ1, at a moment in time at which all of the other gates are at the low level; the charge accumulated in the photodiode PH2 of the preceding pixel being transferred to below the gate G1. This charge is that resulting from the accumulations in the preceding pixels which have viewed the same image strip.

The rising edge of the signal Φ2 then divides this charge between the gates G1 and G2.

The falling edge of the signal Φ1 concentrates this charge below the gate G2.

The falling edge of the signal Φ2 transfers this charge to the photodiode PH1.

The rising edge of the signal RST empties the charge which might have accumulated in the unmasked photodiode PH2 and upholds its removal for the duration of activation of RST. This signal does not affect the masked photodiode and therefore does not change the amount of charge that it contains.

The falling edge of the signal RST defines the start of the actual integration time T_{INT}, since it then allows charge to be accumulated in the photodiode PH2, resulting from the illumination of this photodiode and from the illumination of the gates G3 and G4. The latter are at a low potential and the charge that they generate is immediately transferred to the photodiode PH2. It should be noted that it is possible to make provision for the semiconductor doping below the gate G3 to be slightly different from the doping below the gate G4, in order to facilitate the transfer of their charge to the photodiode PH2.

The accumulation of charge from the current illumination of the pixel then continues in the photodiode PH2.

Before the end of the row period, the signals are the following:
the rising edge of Φ3 creates, below the gate G3, a potential well to which the charge of the photodiode PH1 is transferred (which charge results from the illumination of preceding pixels); the charge resulting from the current illumination will also be directed to below the gate G3;
the rising edge of Φ4 defines another potential well below the gate G4 and the charge is distributed below the gates G3 and G4;
the falling edge of Φ3 concentrates this charge below the gate G4.
Lastly, the falling edge of Φ4 transfers this charge to the photodiode PH2, which then contains the sum of the charge from the illumination of the preceding pixels and from the current illumination of the pixel.

In the embodiment of FIG. 1, the masked gate G1 is considered to be of the same size as the unmasked gates. It is possible to envisage it being of smaller size (in order to avoid an overly substantial decrease in the photosensitive area of the pixel), but it is of course necessary to ensure that the charge storage capacity below this gate is sufficient to collect all of the charge from N pixels having viewed one and the same image point.

Likewise, in the embodiment of FIG. 2, the two subdivisions of the pixel are considered to be of the same size, but it is possible to envisage the masked area being of smaller size than the unmasked area, while still ensuring that the charge storage capacity of the gates and of the photodiodes is sufficient with respect to the requirements (according to the number of rows and according to the envisaged range of illumination).

1. A charge-coupled image sensor operating with time delay and charge integration, the image sensor comprising N adjacent rows of P pixels for observation of one and the same image strip by multiple rows of pixels in succession with summation of the electric charge generated by an image point, for a periodic row duration, in the pixels of the same rank of the various rows, the pixels each comprising a succession, in the direction of movement, of charge storage areas, some of which are photosensitive, the image sensor comprising control means for applying potentials to these areas allowing the storage followed by the directional transfer of charge from one pixel to the next, wherein a pixel is subdivided, in the direction of movement, into at least two adjacent portions, each portion comprising at least one charge storage area that is independent of the storage areas of the other portion while allowing a transfer of charge from the first portion to the second, one of the portions being masked against light and the other portion not being masked against light, the latter comprising at least one photosensitive storage area and a charge removal structure allowing the charge stored in this other part to be removed, the image sensor comprising means for activating the removal structure for a fraction of a row duration, before an adjustable instant in time of the start of actual integration preceding a step of transferring charge from the masked area to the unmasked area.

2. The image sensor of claim 1, wherein the pixel comprises three adjacent gates coming one after the other in the direction of movement, the first gate being masked from light and forming the first portion of the pixel and the other two being lit and forming the second portion of the pixel, the charge removal structure being adjacent to said other two gates.

3. The image sensor of claim 1, wherein the first portion of the pixel comprises in succession, in the direction of movement, two gates and a photodiode, and the second portion also comprises two gates and a photodiode, and the charge removal structure is adjacent to the photodiode of the second portion.

4. An operating method for a charge-coupled image sensor operating with time delay and charge integration, the image sensor comprising N adjacent rows of P pixels for observation of one and the same image strip by multiple rows of pixels in succession with summation of the electric charge generated by an image point, for a row duration, in the pixels of the same rank of the various rows, the pixels each comprising a succession, in the direction of movement, of charge storage areas, some of which are photosensitive, the image sensor comprising control means for applying potentials to these areas allowing the storage followed by the directional transfer of charge from an upstream pixel to a downstream pixel, wherein a portion of the storage areas of each pixel is masked from light and another portion is not masked and is photosensitive, and in that the movement and integration of charge comprise, cyclically with a periodicity equal to one row duration:
the transfer of charge arising from the upstream pixel to a storage area of the masked portion of the downstream pixel;
a command to empty, via a removal drain, the charge contained in the unmasked portion of the downstream pixel, followed by the cessation of this command, defining an instant in time of the start of actual charge integration in the downstream pixel;
simultaneously or separately, the integration of photogenerated charge in the unmasked portion of the downstream pixel and the transfer of the charge stored in the masked portion of the downstream pixel to the unmasked portion.
